(19) United States
(12) Patent Application Publication
(10) Pub. No.: US 2016/0254125 A1
(43) Pub. Date: Sep. 1, 2016

(54) METHOD FOR COATING SURFACES

(71) Applicant: Lam Research Corporation, Fremont, CA (US)

(72) Inventors: Lihua Li HUANG, Pleasanton, CA (US); Evan E. PATTON, Pleasanton, CA (US); Alan POPIOLKOWSKI, Los Banos, CA (US); Brett C. RICHARDSON, San Ramon, CA (US); Hong SHIH, Santa Clara, CA (US)

(21) Appl. No.: 14/634,129

(22) Filed: Feb. 27, 2015

(51) Int. Cl. H01J 37/32; C23C 4/18; C23C 4/06; C23C 4/12; C23C 4/10; C23C 4/08

(52) U.S. Cl. CPC H01J 37/32495; C23C 4/105; C23C 4/08; C23C 4/06; C23C 4/127; C23C 4/18

(57) ABSTRACT

A method for providing a protective layer over a substrate is provided. A ceramic layer is deposited over the substrate, wherein the ceramic layer has a porosity. A localized heating of a region of the ceramic layer to a temperature that causes the ceramic layer to melt without damaging the substrate is provided, wherein the melting the ceramic layer reduces the porosity or seals fissures or columnar grain boundaries. The region of the ceramic layer heated by the localized heating is scanned over the ceramic layer.

### BACKGROUND OF THE INVENTION

The present invention relates to the manufacturing of semiconductor devices. More specifically, the invention relates to coating chamber surfaces used in manufacturing semiconductor devices.

During semiconductor wafer processing, plasma processing chambers are used to process semiconductor devices. Coatings are used to protect chamber surfaces.

### SUMMARY OF THE INVENTION

To achieve the foregoing and in accordance with the purpose of the present invention, a method for providing a protective layer over a substrate is provided. A ceramic layer is deposited over the substrate, wherein the ceramic layer has a porosity. A localized heating of a region of the ceramic layer to a temperature that causes the ceramic layer to melt without damaging the substrate is provided, wherein the melting of the ceramic layer reduces the porosity or seals fissures or columnar grain boundaries. The region of the ceramic layer heated by the localized heating is scanned over the ceramic layer.

In another manifestation of the invention, a method for forming a component of a plasma processing chamber is provided. A ceramic layer is thermal sprayed over the component of a plasma processing chamber, wherein the ceramic layer has a porosity. A localized heating of a region of the ceramic layer to a temperature that causes the ceramic layer to melt without damaging the component is provided, wherein the melting the ceramic layer reduces the porosity or seals fissures or columnar grain boundaries. The region of the ceramic layer heated by the localized heating is scanned over the ceramic layer. The component is mounted in the plasma processing chamber.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIGS. 2A-B are schematic views of a substrate processed according to an embodiment of the invention.

FIG. 3 is a schematic view of a localized heating system that may be used in an embodiment of the invention.

FIG. 4 is a schematic view of an etch reactor that may be used in an embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

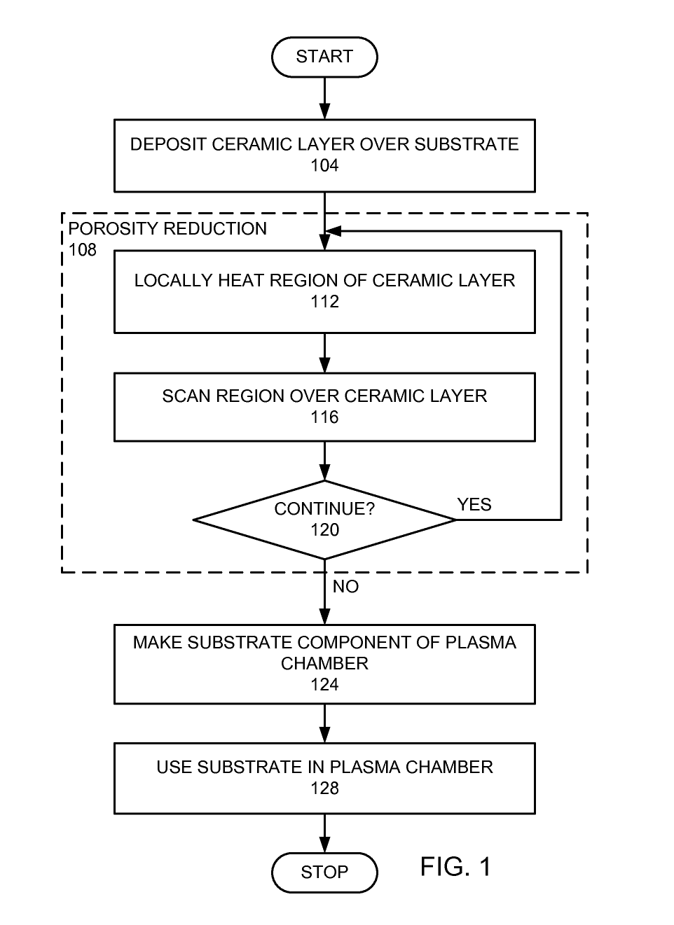

To facilitate understanding, FIG. 1 is a high level flow chart of a process used in an embodiment of the invention. A ceramic layer is deposited over a substrate, where the ceramic layer has a porosity and/or weakly bound particles (step 104). The ceramic layer is subjected to a porosity reduction process (step 108). The porosity reduction process (step 108) comprises the steps of providing localized heating of a region of the ceramic layer to a temperature that causes the ceramic layer to melt without damaging the substrate (step 112), where the melting reduces the porosity in the region of the ceramic layer heated by the localized heating over the ceramic layer (step 116). A determination is made on whether to repeat the process (step 120). If the process is to be repeated, the porosity reduction process is repeated (step 108). If the process is not further repeated, then the substrate is made into a component in a plasma processing chamber (step 124), such as a liner or a covering of another chamber component, or by using the substrate as an electrode. The substrate is then used in the plasma processing chamber (step 128).

### EXAMPLES

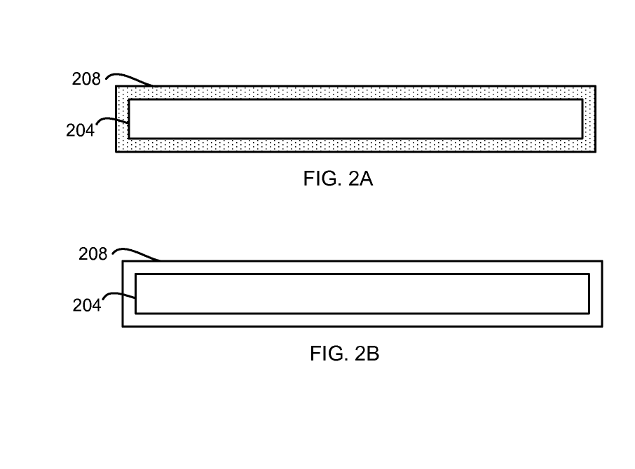

In an example of a preferred embodiment of the invention, a ceramic layer is deposited over a substrate (step 104). FIG. 2A is a schematic cross-sectional view of a substrate 204 with a ceramic layer 208 over the substrate 204. The ceramic layer 208 has a porosity, which is indicated by the shading. In this embodiment, the ceramic layer 208 is deposited by a thermal spray deposition. In other embodiments, the ceramic layer may be deposited by plasma spray, suspension spray, PVD (plasma vapor deposition), CVD (chemical vapor deposition), or aerosol deposition. In this embodiment the substrate is aluminum. In other embodiments, the substrate is alumina, silicon carbide, anodized aluminum, yttria or AlN. In this embodiment, the ceramic layer 208 comprises yttrium oxide (yttria). In other embodiments, the ceramic layer 208 comprises yttrium fluoride, yttrium oxyfluoride (YOF), yttria stabilized zirconia (YSZ), yttrium, cerium oxide, aluminum fluoride, rare earth oxide, or other combinations of ceramic coatings. In some embodiments, the ceramic layer is made of an oxide.

Thermal spraying is a general term used to describe a variety of coating processes, such as plasma spraying, arc spraying, flame/combustion spraying, and plasma spraying. All thermal spraying uses energy to heat a solid to a molten or plasticized state. The molten or plasticized material is accelerated towards the substrate so that the molten or plasticized material coat the surface of the substrate and cool. Preferably, plasma spraying is used to provide the yttria coating. These processes are distinct from vapor deposition processes, which use vaporized material instead of molten material.

The ceramic layer is subjected to a porosity reduction process (step 108). In this process, localized heating of a region of the ceramic layer 208 is provided (step 112) to heat the localized region to a temperature that melts the ceramic coating layer at the localized region without damaging the substrate 204. The energy is primarily dissipated in the top 100 μm or less of the ceramic coating, so that material more than 100 μm from the surface is not melted. More preferably material that is more than 20 μm from the surface is not melted. This requires selection of an energy source that is absorbed by the ceramic coating layer. The melting of the ceramic layer reduces porosity. The melting of the ceramic may also include remelting of the ceramic with multiple exposures and varying energy levels to achieve the desired material properties (ex. melt depth, surface finish).

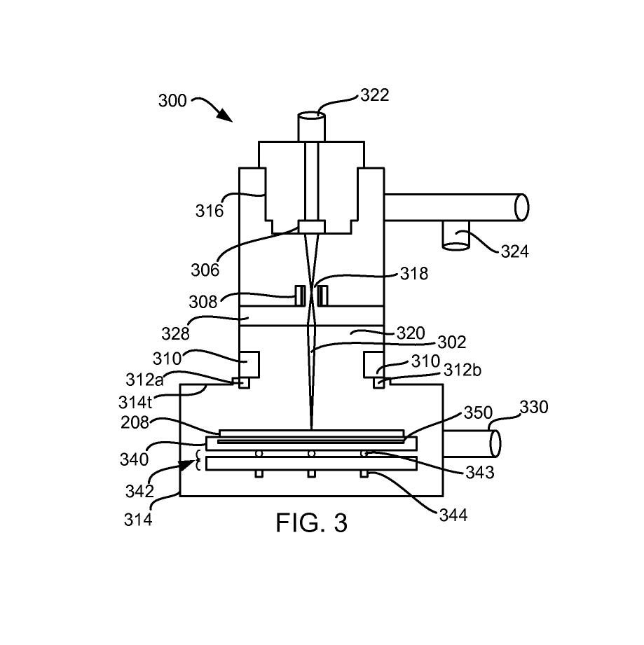

FIG. 3 is a schematic view of a localized heating system 300 for providing the localized heating of the ceramic layer 208 (step 112). The localized heating system 300 comprises a column 320. Located with the column 320 is a bias cup 316 surrounding a cathode 306. The cathode 306 may be, for example, a filament comprising a material such as tungsten. A high voltage cable 322 is coupled to the cathode 306.

Spaced apart from the cathode 306 and beneath the cathode 306 is an anode 308, and two pairs of high speed deflector coils 312a, 312b. A pass through hole 318 is formed within the anode 308. A fast focusing coil 310, typically circular in design and concentric with the column 320 is located beneath anode 308. The two pairs of high speed deflector coils 312a, 312b reside beneath the fast focusing coil 310. Coupled to, and below column 320 is a work chamber 314 with a top surface 314t. The work chamber 314 generally comprises a substrate support 340. The substrate support 340 may be coupled to a two dimensional translation system 342 for independently moving the substrate support 340 in an x direction and a y direction. In this example, the translation system 342 comprises an x stage 343 for moving the substrate support 340 in the x direction and a y stage 344 for independently moving the substrate support 340 in the y direction. The two dimensional translation system 342 moves the substrate relative to the electromagnetic beam 302. The substrate support 340 may further comprise a heating element 350, such as, for example a resistive heater, and/or a heat sink such as a water cooled plate to control the substrate temperature during the process. An isolation valve 328 positioned between the anode 308 and the fast focusing coil 310 and generally divides column 320, so that chamber 314 may be maintained at a pressure different from the portion of column 320 above the isolation valve 328. A first pump 324 is in fluid connection with the column 320. A second pump 330 is in fluid connection with the chamber 314.

While the FIG. 3 specifically depicts localized heating system 300 as an electron beam system, it is within the scope of the invention to use other beams of electromagnetic waves or particles, such as a beam of protons, neutrons, X-rays, or photons in other embodiments for a localized heating system. The localized heating system comprises scanning and focusing systems that depend upon the particular type of electromagnetic radiation employed.

The substrate 204 with the ceramic layer 208 is placed in the localized heating system. A local region of the ceramic layer 208 is heated to a temperature that causes the ceramic layer to melt without damaging the substrate 204, where the melting reduces porosity (step 112). In this example, the pressure in the chamber 314 is reduced to approximately 10⁻³ mbars. An electron beam 302 is formed by heating the cathode 306 and applying a current to the cathode. Electrons escape from the cathode 306 and collect in the bias cup 316. A negative high voltage potential is applied to the cathode 306 relative to the anode 308 via cable 322. The electron beam 302 is directed to the ceramic layer 208 to cause the heating of a localized region of the ceramic layer 208. Preferably, the localized heating system 300 provides an electron acceleration voltage between 30-150 Kv and a current of 0.1-10 mA. The electron beam creates a beam spot on the ceramic layer 208 with a diameter of 80-200 microns, so that the localized heating region directly heated by electrons from the electron beam has a diameter of 80-200 microns.

The heated localized region of the ceramic layer 208 is scanned over the ceramic layer 208 (step 118). In various embodiments the two dimensional translation system 342 or the deflector coils 312a, b, either separately or in combination may be used to provide the scanning. In this embodiment, the scan is Cartesian forming rows and columns along the x and y directions. In other embodiments, the scan may be rotational in a spiral path. The local heating heats the ceramic layer 208 to the ceramic layer's 208 melting temperature causing the ceramic layer 208 to melt and resolidify. In some embodiments, the ceramic layer has been previously melted, so that the melting is a remelting. In this example, it is determined that the localized region will scan over the ceramic layer 208 twice (step 120). In this embodiment, the second scan would be at a different temperature than the first scan. In other embodiments, the second scan would be at the same temperature.

FIG. 2B is a schematic cross-sectional view of a substrate 204 with a ceramic layer 208 over the substrate 204 after the localized region has been scanned over the ceramic layer 208 twice. The process has reduced the porosity, as indicated by the reduced shading.

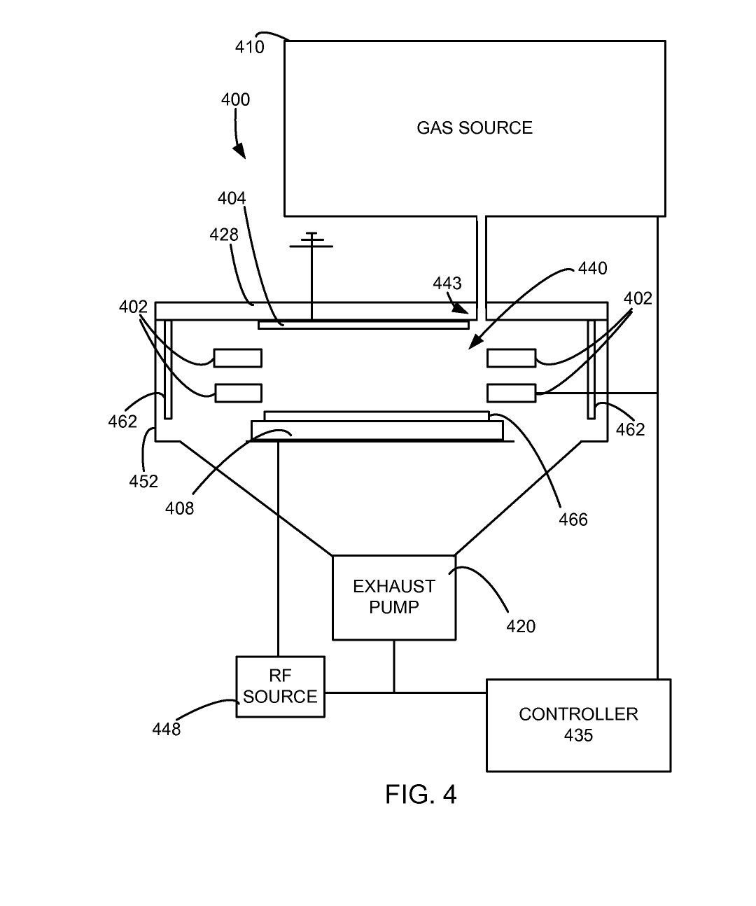

The substrate 204 is then made part of a plasma processing chamber (step 124). FIG. 4 is a schematic view of a plasma processing chamber 400 in which the substrate has been mounted. The plasma processing chamber 400 comprises confinement rings 402, an upper electrode 404, a lower electrode 408, a gas source 410, a liner 462, and an exhaust pump 420. The liner 462 is formed from the substrate with the remelted ceramic layer. Within plasma processing chamber 400, a wafer 466 is positioned upon the lower electrode 408. The lower electrode 408 incorporates a suitable substrate chucking mechanism (e.g., electrostatic, mechanical clamping, or the like) for holding the wafer 466. The reactor top 428 incorporates the upper electrode 404 disposed immediately opposite the lower electrode 408. The upper electrode 404, lower electrode 408, and confinement rings 402 define the confined plasma volume 440.

Gas is supplied to the confined plasma volume 440 through a gas inlet 443 by the gas source 410 and is exhausted from the confined plasma volume 440 through the confinement rings 402 and an exhaust port by the exhaust pump 420. Besides helping to exhaust the gas, the exhaust pump 420 helps to regulate pressure. An RF source 448 is electrically connected to the lower electrode 408.

Chamber walls 452 surround the liner 462, confinement rings 402, the upper electrode 404, and the lower electrode 408. The liner 462 helps prevent gas or plasma that passes through the confinement rings 402 from contacting the chamber walls 452. Different combinations of connecting RF power to the electrode are possible. In a preferred embodiment, the 27 MHz, 60 MHz and 2 MHz power sources make up the RF power source 448 connected to the lower electrode 408, and the upper electrode 404 is grounded. A controller 435 is controllably connected to the RF source 448, exhaust pump 420, and the gas source 410. The process chamber 400 may be a CCP (capacitive coupled plasma) reactor or an ICP (inductive coupled plasma) reactor or other sources like surface wave, microwave, or electron cyclotron resonance ECR may be used.

The substrate is then used in the plasma processing chamber (step 128). In use, the wafer 466 is placed on the lower electrode 408. Plasma processing gases such as etch gases or deposition gases are flowed from the gas source 410 into the plasma processing chamber 400. In this example the plasma processing gas has components comprising hydrogen and halogens. The plasma processing gas is formed into a plasma for plasma processing. Some of the halogen and hydrogen containing components deposit on the liner 462. When the chamber is opened, the hydrogen and halogen components form an acid with water vapor. With a high porosity, the ceramic layer would expose the substrate to the acid, which would cause the substrate to corrode. The heat treatment has reduced porosity, which improves the protection of the substrate by the ceramic layer from acid.

Preferably, porosity of the ceramic layer is greater than 5% before treatment and less than 1% after treatment. In another embodiment, the porosity of the ceramic layer is greater than 1% before treatment and less than 0.5% after treatment. In both cases, porosity is reduced by at least 50%. Preferably, the localized heating has a melt depth of less than 100 microns. This low melt depth allows for the ceramic to be melted to reflow the ceramic without damaging or melting the substrate. In some embodiments, material in the ceramic layer is melted for the first time. In other embodiments, material in the ceramic layer is remelted. In other embodiments, some of the material is melted for the first time while other material is remelted. In some embodiments, the substrate is Al, anodized Al or alumina, and the locally heated region heats the ceramic layer to a temperature of at least 1800° C. Preferably, when an electron beam is used the localized regions being melted have a diameter of less than 100 μm. When a laser beam is used, the localized regions being melted have a diameter less than 5 cm.

In a preferred embodiment, the electron beam is continuous, instead of pulsed, to allow a continuous scanning, providing a more even melting of the ceramic layer. In one embodiment, the ceramic layer consists of high purity yttria, which is defined as being greater than 95% pure. In such an embodiment, a laser may be used to provide localized heating.

In some embodiments, the melted ceramic layer has improved uniformity, density, purity, and surface finish to improve chemical and plasma resistance. The remelting may also be used to seal columnar grain boundaries of a PVD process. The remelting may also reduce coating pits and low density area aerosol deposition, increase coating hardness, and fracture toughness. In some embodiments, the ceramic layer is heated to a temperature above 2200° C. without damaging the underlying aluminum with a melting point of around 660° C. or alumina substrate, which has a much higher melting temperature.

In some embodiments, various controls of the localized heating device may be used to provide a controllable heating depth. For example the bias voltage of the ion beam may be used to increase or decrease the heating depth, which controls the depth to which the ceramic melts. Preferably the melt depth is less than 100 microns. More preferably, the melt depth is less than 50 microns. Most preferably, the melt depth is less than 20 microns.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for providing a protective layer over a substrate, comprising depositing a ceramic layer over the substrate, wherein the ceramic layer has a porosity;
providing a localized heating of a region of the ceramic layer to a temperature that causes the ceramic layer to melt without damaging the substrate, wherein the melting of the ceramic layer reduces the porosity or seals fissures or columnar grain boundaries; and
scanning the region of the ceramic layer heated by the localized heating over the ceramic layer.

2. The method, as recited in claim 1, wherein the providing the localized heating, comprises providing a beam of electromagnetic energy.

3. The method, as recited in claim 2, wherein the beam of electromagnetic energy is an electron beam

4. The method, as recited in claim 3, wherein the melt depth is less than 100 microns.

5. The method, as recited in claim 4, wherein the porosity of the deposited ceramic layer is greater than 5% before providing the localized heating and less than 1% after providing the localized heating.

6. The method, as recited in claim 5, wherein scanning the region of the ceramic layer heated by the localized heating over the ceramic layer scans over the ceramic layer at least twice.

7. The method, as recited in claim 6, wherein the providing the localized heating of the region of the ceramic layer remelts part of the ceramic layer.

8. The method, as recited in claim 7, further comprising placing the substrate in a plasma processing chamber.

9. The method, as recited in claim 7, wherein the substrate is an aluminum containing material and wherein the localized heating heats the ceramic layer to a temperature of at least 1800° C.

10. The method, as recited in claim 7, wherein the substrate comprises Al or alumina and wherein the localized heating heats the ceramic layer to a temperature of at least 1800° C.

11. The method, as recited in claim 10, wherein the depositing of the ceramic layer comprises providing a thermal spray coating.

12. The method, as recited in claim 11, wherein the ceramic layer comprise at least one of alumina (Al₂O₃), AlFₓ, CeO₂, yttria (Y₂O₃), Y, yttria stabilized zirconia (YSZ), YFₓ, or YOF.

13. The method, as recited in claim 2, wherein the beam of electromagnetic energy is a laser beam.

14. The method, as recited in claim 1, wherein the melt depth is less than 100 microns.

15. The method, as recited in claim 1, wherein the porosity of the deposited ceramic layer is greater than 2% before providing the localized heating and less than 1% after providing the localized heating.

16. The method, as recited in claim 1, wherein scanning the region of the ceramic layer heated by the localized heating over the ceramic layer scans over the ceramic layer at least twice.

17. The method, as recited in claim 1, further comprising placing the substrate in a plasma processing chamber.

18. A method for forming a component of a plasma processing chamber, comprising
thermal spraying a ceramic layer over the component of a plasma processing chamber, wherein the ceramic layer has a porosity;
providing a localized heating of a region of the ceramic layer to a temperature that causes the ceramic layer to melt without damaging the component, wherein the melting the ceramic layer reduces the porosity or seals fissures or columnar grain boundaries;
scanning the region of the ceramic layer heated by the localized heating over the ceramic layer;
mounting the component in the plasma processing chamber.
